(19) United States
(12) Patent Application Publication
(10) Pub. No.: US 2011/0261602 A1
(43) Pub. Date: Oct. 27, 2011

(54) MAGNETIC MEMORY DEVICES AND SYSTEMS

(75) Inventors: Christoforos Moutafis, Zurich (CH); Stravros Komineas, Crete (GR)

(73) Assignee: ECOLE POLYTECHNIQUE FEDERALE DE LAUSANNE (EPFL), Lausanne (CH)

(21) Appl. No.: 12/994,241

(22) PCT Filed: May 26, 2009
(86) PCT No.: PCT/GB2009/050569

§ 371 Date: Feb. 3, 2011

(30) Foreign Application Priority Data
May 23, 2008 (GB) 0809403.9

(51) Int. Cl. G11C 19/08

(52) U.S. Cl. 365/8; 365/1; 365/7

(57) ABSTRACT

A method of storing one or more bits of information comprising: forming a magnetic bubble; and storing a said bit of information encoded in a typology of a domain wall of said magnetic bubble. Preferably a bit is encoded using a symmetric topological state of the domain wall and a topological state including at least one winding rotation of a magnetisation vector of the domain wall. Preferably the magnetic bubble is confined in an island of magnetic material, preferably of maximum dimension less than 1 μm.

### FIELD OF THE INVENTION

This invention relates to techniques for storing information using magnetic bubbles. Embodiments of the application have applications in data storage, in particular because they offer a technique for switching very fast between two or more distinct states. However embodiments of the techniques we describe may also be employed for other applications, for example tagging, in particular of very small entities such as chemical or biological entities—cells, molecules and the like.

### BACKGROUND TO THE INVENTION

There are many prior art documents which relate to the use of magnetic bubbles to store information. One of the main ideas in the field was to use many bubbles on the same medium, finding techniques to keep them separated enough but stable, and to move them around to induce data/logic operations.

Background prior art can be found in: U.S. Pat. No. 4,068,220, U.S. Pat. No. 3,793,639, U.S. Pat. No. 3,842,407, U.S. Pat. No. 3,936,883, U.S. Pat. No. 3,689,901, U.S. Pat. No. 3,935,594, U.S. Pat. No. 3,793,640, U.S. Pat. No. 5,392,169, U.S. Pat. No. 4,085,454, U.S. Pat. No. 3,996,577, U.S. Pat. No. 4,181,977, U.S. Pat. No. 4,974,200, U.S. Pat. No. 4,001,794, U.S. Pat. No. 5,050,122, U.S. Pat. No. 4,926,377, U.S. Pat. No. 5,260,891, U.S. Pat. No. 5,023,473, U.S. Pat. No. 5,910,861.

Further background prior art is mentioned in the list of references at the end of the description.

By contrast preferred embodiments of the techniques we describe employ patterned media, more particularly nanostructures where each structure comprises an actual physical bit of information. We have previously demonstrated that high perpendicular anisotropy nanostructures such as nano-dots can provide stable bubbles without the need for an additional external bias field. In some of the nanostructures we describe substantial magnetic isolation between the domains is achieved by providing a sufficient inter-dot distance.

Particular reference can be made to C. Moutafis et al, Phys. Rev. B 76, 104426 (2007), which describes the fabrication of high-quality circular FePt nanodots. As explained in the Experimental Methods section of the paper: Films of FePt in the tetragonal L1₀ phase were patterned into arrays of circular dots. The thin films were prepared using UHV magnetron sputtering apparatus—an Fe seed layer 1 nm thick and a 40 nm thick Au(001) buffer layer was deposited on MgO(001) single crystal substrates at room temperature followed by a 50 nm thick FePt(001) layer epitaxially grown at 300° C. on the Au buffer layer. The film composition (Fe₃₈Pt₆₂) was determined by electron probe x-ray microanalysis. The dot arrays were fabricated using electron beam lithography and Ar ion milling, giving arrays of dots with lateral sizes D=0.5, 1, 2 and 5 μm and a spacing between dots approximately equal to their lateral size. Triple-domain states comprising concentric rings with alternating magnetization were observed. A numerical study confirmed the range of stability of the observed magnetic states. FIG. 1 shows the predicted phase diagram in parameter space for varying dot thickness t and radius R (both in units of exchange length lₑₓ, assumed 4.0 nm for these FePt dots). The regimes where the single-domain, the monobubble and the three-ring states are energetically favourable are indicated for thickness in the range 5lₑₓ<t<12.5lₑₓ (or 20 nm<t<50 nm).

### SUMMARY OF THE INVENTION

According to a first aspect of the invention there is therefore provided a method of storing one or more bits of information, the method comprising: forming a magnetic bubble; and storing a said bit of information encoded in a topology of a domain wall of said magnetic bubble.

In preferred embodiments a bit is encoded using S=0 and S=1 states of the domain wall, the S=1 state comprising a symmetric state of the domain wall, the S=0 state including a topological defect, in embodiments a winding rotation of a magnetisation vector in moving around a border of the bubble defined by the domain wall. In embodiments a bubble is substantially circular, but this is not essential.

Changes in the dynamical response of the S=1 and S=0 bubble as well as their corresponding switching are not limited to a specific magnetic field form or to a magnetic field as an external probing. An external probing with charge current or spin-polarised current could also induce such changes. More than one magnetic field form can be envisioned/implemented and corresponding current based changes can also be achieved. Thus one can potentially modify the nature of the pulses for better/more efficient/faster dynamics and switching; one could also use another probing-like current.

Preferably the magnetic bubble is confined in an island of magnetic material, for example an FePt nano-dot, in particular with perpendicular anisotropy. Thus in embodiments the bubble is substantially stable without the application of a bias field. Each island may store only a single magnetic bubble, although each may bubble encode one or more bits (depending upon the topological states employed). In embodiments a value of a bit may be changed by applying a magnetic field gradient pulse to the bubble.

In a related aspect the invention provides a magnetic storage device for storing one or more bits of information, the device comprising: a plurality of islands of magnetic material; a plurality of magnetic bubbles, at least one per said island; wherein said bits of information are stored encoded in a topology of a domain wall of said magnetic bubble.

In some preferred embodiments an island of the magnetic material has a maximum dimension of less than 1 μm. In embodiments bits of information are stored encoded in a topology of a domain wall of said magnetic bubble and/or with the additional use of higher order bubbles like the three-ring state and/or the single domain.

The invention still further provides a method of reading a bit of information, the method comprising applying a magnetic field to induce different dynamic responses from said topology of said domain wall, and detecting a said dynamic response to identify a said topology of said domain wall of a said magnetic bubble and hence deduce a value of a stored said bit of information.

In embodiments of the method the topological state of the domain wall may be interrogated by applying a field gradient pulse or by applying a magnetic field to cause rotation of a topological defect (where present), and detecting such rotation for example via its AC field. Additionally or alternatively a field may be applied to change size of a magnetic bubble to identify whether or not a topological defect is present and/or the type of defect.

In a still further aspect the invention provides a device for reading a bit of information, the device comprising: means for applying a magnetic field to induce different dynamic responses from said topology of said domain wall; and means for detecting a said dynamic response to identify a said topology of said domain wall of a said magnetic bubble and hence deduce a value of a stored said bit of information.

In embodiments the dynamic response may be detected by its electrical signature, in for example by means of magnetoresistive measurements. In embodiments applying an oscillating magnetic field tuned to the S=1 bubble's eigenfrequency would induce a regular/periodic motion with a corresponding electrical signature.

In embodiments of the above-described methods and devices a pair of conductors may be provided, one to either side of a magnetic bubble or island/nano-dot for reading and/or writing a topological state of a domain wall of a magnetic bubble.

The invention also provides a mechanism (method and apparatus) for reading information that includes a storage (“free”) layer where topological magnetic states, in particular as described, here are formed; a reference layer; a non-magnetic layer; electrodes of various possible geometries for electrical current injection.

### BRIEF DESCRIPTION OF THE DRAWINGS

These and other aspects of the invention will now be further described, by way of example only, with reference to the accompanying figures in which:

FIG. 1 shows a predicted phase diagram in parameter space for varying FePt dot thickness t and radius R (both in units of exchange length lₑₓ).

FIG. 2a shows magnetic imaging of a dot with diameter D-500 nm in the monobubble state. The difference in contrast reveals two domains of anti-parallel out-of-plane magnetization.

FIG. 2b shows monobubble state on the left; a unichiral bubble with winding number S=1. On the right we have the resulting bubble with S=0. In the top right part of the circular domain wall the 360° degrees “defect” is visible. Red and blue signify out-of-plane parallel magnetization.

FIG. 2c shows an example implementation of a reading mechanism.

FIGS. 3a and 3b show bubbles with (a) N=1 and (b) N=0. Only the domain wall is shown. We suppose that the magnetization points “down” inside the wall while it points “up” outside it.

FIG. 3c shows the orbit of the bubble under an external field gradient (6) with g=−0.0025. The solid line shows the coordinates (Rₓ, R_{y}) of Eq. (8). The dashed line shows the coordinates (X,Y) of Eq. (7). The circles mark the bubble position at times which are multiples of 5.33τ₀(15 ps). The arrows indicate the point where the field is switched off.

FIG. 3d shows snapshots from the simulation for a bubble with N=1 under external field gradient (6) with g=−0.0025. They show the bubble (a) at the dot centre (at time τ=0), (b) when the external field is switched-off [r=44.5τ₀(200 ps)], and (c) when this has completed a cycle around the dot centre [τ=267τ₀ (1200 ps)].

FIG. 4 shows the trajectory of the bubble under external field gradient (6) with g=−0.025. The solid line shows the coordinates (Rₓ, R_{y}) of Eq. (8). They have been traced until τ=85.5τ₀ when we have switching. The dashed line shows the coordinates (X,Y) of Eq. (7), which have been traced until τ=432τ₀.

FIG. 5 shows snapshots from the simulation for a bubble under external field gradient (6) with g=−0.025. (a) A remanent N=1 bubble in the dot center (τ=0), (b) the instant just before the wall unwinding [τ=83τ₀ (375 ps)] where the arrow indicates the area where the VBLs have developed, and (c) the instant just after the wall unwinding [τ=85.5τ₀ (385 ps)] where the arrow indicates the same area as in the previous entry. (d) A N=0 bubble as a remanent state (at the end of the simulation).

FIG. 6 shows blow-ups of a part of the bubble which contains Bloch lines for (a) FIG. 5b and (b) FIG. 5c (the arrows correspond to those in FIG. 5).

FIG. 7 shows the trajectory of a N=0 bubble which is subject to an external field (6) with g=−0.025. The field is switched off at τ=55τ₀(250 ps). The bubble switches to a N=1 bubble at τ=98τ₀(440 ps), which is indicated by the arrows. We plot both the coordinates (8) (solid line), which are defined only after the switching for N=1, and the coordinates (7) (dashed line). The total simulation time is τ=555.5z₀(2.5 ns).

FIG. 8 shows snapshots from the simulation for a bubble under external field gradient (6) with g=−0.025. (a) A remanent N=0 bubble in the dot center (at τ=0), (b) the instant just before the wall unwinding where the arrow indicates the area where the VBLs have developed [τ=95.5τ₀ (430 ps)], and (c) the instant just after the wall unwinding where the arrow indicates the same area as in the previous entry [τ=98τ₀ (440 ps)]. (d) The final results of the simulation, i.e., a static N=1 bubble.

FIG. 9 shows blow-ups of a part of the bubble corresponding to (a) FIG. 8b and (b) FIG. 8c (the arrows correspond to those in FIG. 8).

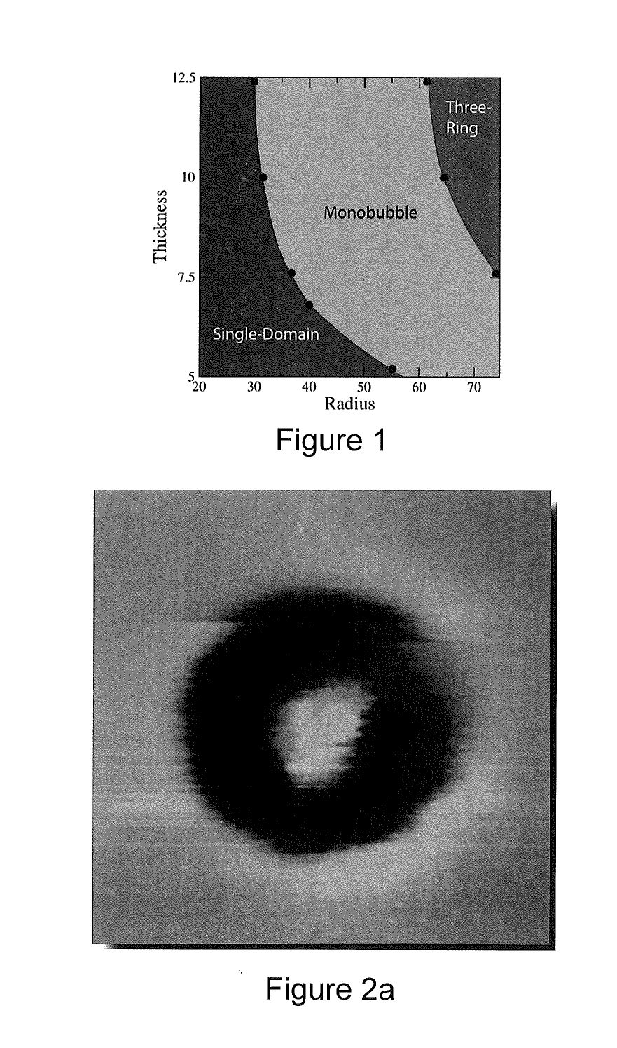

### DETAILED DESCRIPTION AND PREFERRED EMBODIMENTS

Broadly speaking we will describe topological switching of magnetic elements for memory applications. The techniques we describe provide a novel way of encoding and reading information on ferromagnetic elements in the nano-scale regime. Applications relate to the field of magnetic memory and in particular MRAM-type memories. Embodiments of the invention also address needs where coding information on a nano-sized element can provide benefits, for example for magnetic tagging of biological molecules. Embodiments of the technique offer the potential for: (i) ultra-fast switching mechanisms (ii) multi-bit information encoding, and (iii) dense recording.

Some advantages of the technique in relation to the prior art are as follows:

(i) Switch is faster by an order of magnitude, 100 nanoseconds (ns)->a few ns;
(ii) The magnetic states are stable in equilibrium without need of stabilising field;
(iii) Film preparation has less requirements (no need for exchange couple layer);
(iv) Patterned media offer physical separation of magnetic domains;
(v) Two concepts for a reading mechanism are suggested.

Some further distinctive characteristics of our system are as follows:

We switch between bubbles of different topology (winding number) for example between S=1 and S=0. We do not need a bias field because the bubbles we employ can be stable in nanostructures with suitable characteristics. We employ the bubble itself, more particularly the domain wall of the bubble, to hold information. Embodiments of the techniques we describe do not require domain propagation—although in one of the reading techniques we describe there is some domain motion, this is small, in particular due to confinement within the nano-dot. Preferred embodiments employ sub-micrometre nano-dots, potentially even sub 500 nm, 200 nm or 100 nm, which is useful for dense information encoding. In embodiments of the nanostructure each bit is physically separated from the others. Moreover the magnetic bubbles do not need to propagate; they exist within the nano-dots and dynamic responses induced by interaction with the bubbles are achieved via conductors parallel to the nano-dots. Thus, for example, in embodiments of the technique we describe there is actual interaction of a low current with the magnetisation in the dot.

In a bubble with S=0 changing the size/diameter of the bubble will make the “defect” in the wall rotate, and the frequency of this rotation can be detected. In an S=1 bubble, although the change in its size could give changes in a reading electrical signal. This would not provide a signal at a frequency of a rotating “defect” since an S=1 bubble does not have such a signature. Embodiments of the techniques do not need to use the bubble's stray fields for reading/sensing or for writing. Again, as previously noted, we do not need a bias field to maintain the bubbles on the dot after finishing operations on them: “data” (that is bubble states) are stable and retained; a bubble domain wall of a bubble in a nano-dot constitutes one or more bits of information.

We describe an ultra-fast mechanism to switch between two different magnetic configurations/states on a time scale of nanoseconds.

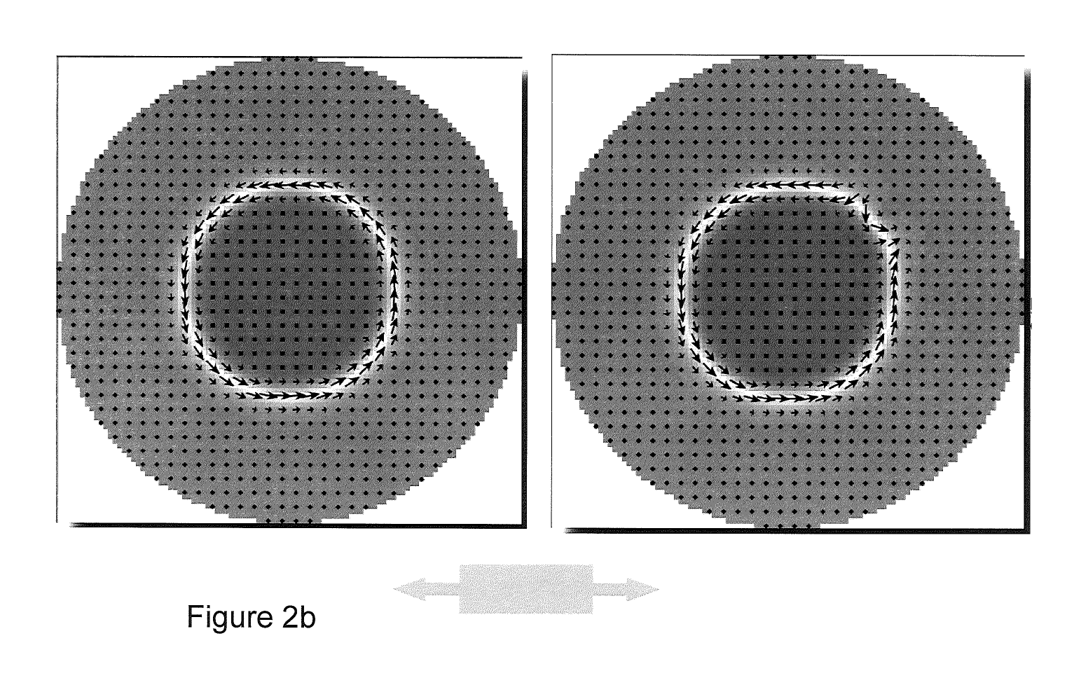

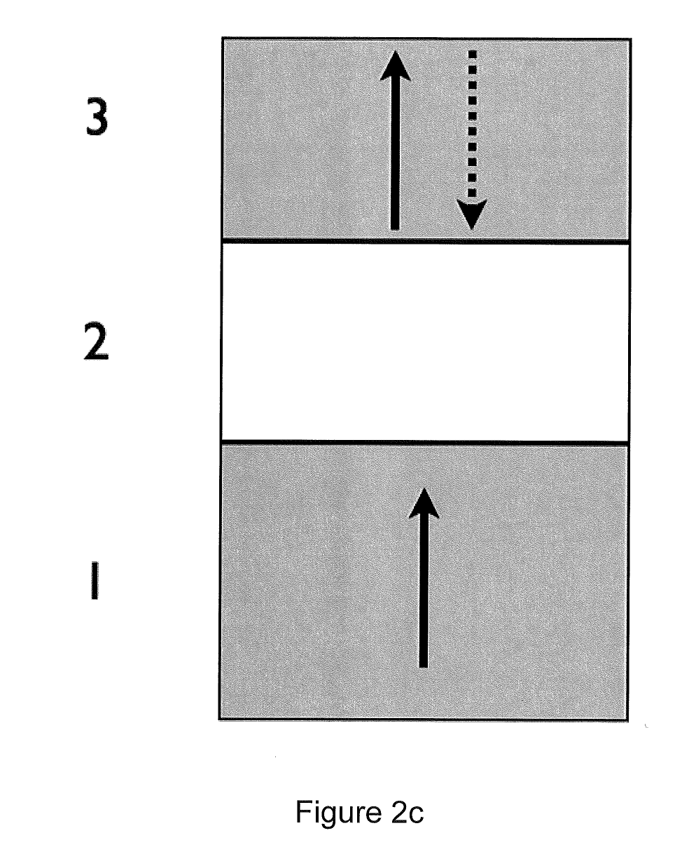

Bubble domains were recently identified on technologically relevant high perpendicular anisotropy nano-dots. In Ref [1] it was showed that the bubble domains could be stabilised in elements with very high perpendicular anisotropy materials, without a need for a bias field (FIG. 2a). We called this state the monobubble state, comprising of a circular magnetic bubble with an axially symmetric domain wall confined in the middle of the dot.

Bubbles appear primarily in materials with perpendicular anisotropy. They are cylindrical domains of out-of-plane magnetization anti-parallel to its surrounding magnetization. A domain wall between the two domains delineates the bubble. Bubbles have been extensively studied in films [2-4] and their potential for devices has been actively explored [e.g. 3]. The internal structure of the bubble domain wall hides extra degrees of freedom [3, pp 507] that can be exploited for memory-based applications [5-7].

Different kinds of bubbles can be identified depending on the structure of their domain wall; that is the winding (number of revolutions) of the magnetization vector as we move around the wall. A measure of the topological structure of these domains is the so-called winding number S [2]. A large number of distinct bubble domains are accessible and would behave differently dynamically under the same external probing [2, 8]. Effectively this means that we can encode/write information on a bubble's domain wall.

Recent remarkable advances in fabrication allow for the making of magnetic elements with sizes ranging from hundreds to tens of nanometres.

We have shown experimental evidence for the monobubble state [1] on an element with very high anisotropy and we have identified computationally a mechanism to switch from a bubble with winding number S=1 (state A) to a bubble with winding number S=0 (state B) (see FIG. 2b) and back, by effectively introducing a “defect” on a bubble's domain wall in an ultra-fast process.

### Writing

By applying a field gradient along the diameter of a dot in the monobubble state we induce the dynamic response of the bubble. The field gradient can be achieved by current pulses in two conductors/wires on each side of the dot. By fine-tuning the strength and the duration of the pulse we can create a distinct bubble with different topology, which stabilises in the centre of the dot in equilibrium. The S=1 bubble has an axially symmetric wall. The bubble with winding number S=0 is no longer axially symmetric but a small part of the wall, as we move around it, includes a 360o degrees rotation of the magnetization vector; we could also call this a “defect/kink”.

This kind of state emerges clearly in elements in our simulations and has previously been described theoretically and experimentally [2-4] in films. It has been shown to behave differently dynamically than the S=1 bubble in Ref. [4].

Example: We have a dot with the following geometrical and materials characteristics: a diameter D=160 nm, thickness t=32 nm, uniaxial anisotropy constant Ku=1.3×106 J/m and saturation magnetization Ms=10̂6 A/m. The strength of the employed field gradient is approx. [−0.5 Ms:0.5 Ms] across the dot radius.

We apply a field gradient pulse, across the dot's diameter, which we call for convention the x-axis. The pulse is t=45 picoseconds long.

The S=1 bubble starts moving at an angle to the field gradient and we observe changes in the local topological density. In approx. half a nanosecond the global topology has already changed into S=0. The new bubble though needs some time before it relaxes in the centre of the dot. The whole procedure including the relaxation period, for the above dot and pulse characteristics is approx. 5 nanoseconds (The actual switch process is sub-nanosecond long).

It should be noted that we can tune the field gradient pulse strength and duration as well as the dot's diameter and thickness in order to exhibit the same mechanism with lower field strengths.

### Reading

A magneto-resistance read approach is suggested. A low current passed through the dot when in state S=1 or state S=0 would give an electrical signature. These two states would behave differently under the same external probing and thus give a distinct electrical response. There are two novel suggested mechanisms to deduce the state on the dot:

We start with a simple field gradient pulse that can be applied with the same set-up we use for the writing. The S=1 bubble would move at angle with the applied field gradient (bubble skew deflection) while the S=0 bubble would move across the field gradient. This should give a different electrical response. When the pulse stops, the S=1 bubble would exhibit a regular orbit (a damped periodic motion) back to its equilibrium point in the centre of the dot. For the dot characteristics described above, this would correspond to a frequency of approx. 1 Ghz (the S=1 bubble's eigenfrequency), while the S=0 bubble would exhibit a non-regular orbit.

A simple out-of-plane uniform bias field, depending on its direction, would expand or shrink the bubble until the new equilibrium position is reached. We can thus—at will—increase or decrease the size of the bubble switching on and off a simple field. We observe on simulations that in the S=0 bubble the “defect” on its wall would rotate across the wall during the application of the field, that is during the expansion or shrinking of the bubble. This rotation can be reversed as many times as needed to sustain a regular behaviour that should lead to a corresponding electrical signature with some form of regular/periodic characteristics. At the same time exciting the S=1 bubble in its eigenfrequency with an oscillating (e.g. in-plane) magnetic field would also sustain a regular/periodic motion with a corresponding electrical signature.

An example implementation of a reading mechanism can be seen in FIG. 2c. A multilayer sandwich-type structure for a magnetic random access memory architecture is proposed. The structure includes a magnetic storage (free) layer (3), a non-magnetic layer (spacer) (2), a magnetic reference layer (pinned or hard magnetic layer) (1).

The spacer can include materials like Al203, Cu. The free (storage) layer is a ferromagnetic circular dot like (but not limited to such a geometry). The reference (hard or pinned) layer is magnetised along z-axis (either towards the positive or the negative z-axis; any choice can be made initially, but then the layer's magnetisation direction will be fixed). One possibility is for it to be thicker in order for the magnetisation to be strongly aligned towards the z-axis.

In the storage (free) layer a bubble state will exist. When electrical current flows through the device there will be a certain magnetoresistance signature. This can be influenced by the external magnetic field. By exciting the S=0 bubble with a uniform pumping perpendicular magnetic field there will be rotation of the Bloch-lines along the bubble's domain wall giving a corresponding frequency in the electrical signature. The same field in the S=1 bubble would give a different electrical signature due to the lack of the Bloch lines pair. In addition, the eigenfrequency of the S=1 bubble can be excited in order to get a distinct electrical signal from this state.

Spin polarised current can be used to induce the aforementioned changes through the spin-torque effect instead or assistive to using the magnetic field. The current could also be used to nucleate a reverse domain which should give a stable bubble for the right dimensions based on our calculations.

The electrical current passing through the multilayer structure is sandwiched between two electrodes (e.g. Cu) through which the electrical current passes.

The structure can also include an extra layer of perpendicular magnetised spin.

### Advantages and Improvements Over Existing Methods, Devices or Materials

We can now perform topological switching on a bubble in a finite geometry (elements) due to the advent of advanced micro-fabrication techniques. What is more, bubbles in nano-elements can be stabilised in equilibrium without the need of a bias perpendicular out-of-plane field, as was the case in films. Bubbles beforehand were considered stable in a certain bias field interval [4, pp 588]. This reduces the need for an extra component; no need for an additional permanent magnet on the device.

Hsu [5,6] uses an exchanged coupled layer or ion-implanted film. The exchange-coupled layer or the ion-implantation is used for the suppression of hard magnetic bubbles. Hard magnetic bubbles have closely packed topologically defects around their

domain wall, which would be unfavourable for applications. In our case this is not needed.

Both S=0 and S=1 states in Refs [5,6] are statically stable only for a certain range of in-plane field. In our case, once the transformation has occurred, there is no need for a field but the states remain stable without external bias. A combination of an in-plane field and domain wall velocity is used for the switching and beyond a critical value only the S=1 bubble is stable [5,6]. In our case, the bubbles are stable in equilibrium. This is a crucial advantage.

Here we have an ultra-fast process. In Refs [5,6] 100 nanosecond long current pulses are used. Here the relevant time scale is a few nanoseconds. An ultra-fast mechanism was identified to switch from state A to stage B and back which is in the range of nanoseconds. For comparison, DRAM, one of the faster memory types has read/write times form 30 ns to 50 ns [e.g. U1].

The simulations supporting this application involve nano-elements (nano-dots) of diameter D=160 nm. It is known that smaller dots can sustain a bubble domain, e.g. a bubble state with a diameter approx. 100 nm has been calculated to be stable [9]. Each dot would be the main component around which a device will be fabricated. For reference, for a cell of current commercial state-of-the art MRAM cell, the minimum feature is defined by an 180 nm-generation technology while the size of the actual cell spans 20 to 30 F2 (F, is minimum cell feature and it equals 400 nm).

Non-Volatile Memory and Data Retention without Power

Patterned media offer themselves for natural separation of bubbles that facilitate minimising interactions in relation to the film case. Interaction for a strictly data storage scheme would be undesirable.

Potentially more than two states can be accommodated, by injecting more defects in the wall and by exploiting the three-ring state and the single-domain state, [1]. Clear potential for multi-bit element/tag. It should be noted that we are not limited by the use of the FePt material (CoPt would also be a suitable candidate). By varying the anisotropy and the size of the dot we can explore the appearance of the mechanism for nanostructures and time-scales of various size and length. It is an advantage of FePt that by heat-treating it we induce better regularity in its lattice and tune its anisotropy. Similarly, by exploring different materials (e.g. Co or Ni) we can achieve different anisotropies. By changing our fabrication we can make dots of different lateral size and thickness. It should also be noted that we are not limited on the geometry of the elements; in fact the states observed are generic of the system and should manifest themselves on, e.g. square dots, ellipses, hollow geometries etc.

### Dynamics and Switching Processes for Magnetic Bubbles in Nanoelements

We have studied numerically the dynamics of a magnetic bubble in a disc-shaped magnetic element which is probed by a pulse of a magnetic field gradient. Magnetic bubbles are nontrivial magnetic configurations which are characterized by a topological (skyrmion) number N and they have been observed in mesoscopic magnetic elements with strong perpendicular anisotropy. For weak fields we find a skew deflection of the axially symmetric N=1 bubble and a subsequent periodic motion around the center of the dot. This gyrotropic motion of the magnetic bubble is shown here for the first time. Stronger fields induce switching of the N=1 bubble to a bubble which contains a pair of Bloch lines and has N=0. The N=0 bubble can be switched back to a N=1 bubble by applying again an external field gradient. Detailed features of the unusual bubble dynamics are described by employing the skyrmion number and the moments of the associated topological density.

Magnetic bubbles are observed as spots of opposite magnetization in an otherwise uniformly magnetized film. The statics and dynamics of magnetic bubbles are complex. One of the most interesting phenomena is their response to an external inhomogeneous field. In a counterintuitive way, they are deflected at an angle to an external magnetic field gradient. This is directly connected to their nontrivial topological structure. They carry a topological number called the skyrmion number which enters in a collective coordinate description of bubble dynamics.

Single magnetic bubbles can be sustained in disc-shaped magnetic elements with perpendicular anisotropy. Although these have the same gross features and the same topological structure as their counterparts in films, their statics is significantly different. Magnetic bubbles in disc elements are sustained without an external field and they may be ground magnetic states for magnetic elements of appropriate sizes. A detailed study of magnetic bubbles in FePt nanodots [ibid] was carried out using numerics and Magnetic Force Microscopy (MFM) imaging of arrays of dots with various diameters. In particular, almost circular magnetic bubbles confined in the center of the dots were observed as a common bidomain state in sufficiently small dots. Tridomain states which have the form of concentric rings with alternating magnetization were also observed, and they can be interpreted as multidomain magnetic bubbles.

Magnetic vortices are spontaneously created in magnetic elements with no or a small magnetic anisotropy. The dynamics of vortices has been observed in time-resolved experiments which revealed the profound role of the vortex polarity on their dynamics. This means that the vortex topological structure is closely related to their dynamics, as also noted above for magnetic bubbles.

We now describe bubble dynamics in magnetic nanoelements. The observations of magnetic bubbles of various topological structures suggest that perpendicular anisotropy dots can be used to significantly widen the scope for dynamical experiments in ferromagnetic elements, beyond the current work on vortex dynamics. We expect an unusual dynamical behavior. The dynamics of bubbles should be expected to bare similarities to that of vortices because they both carry a nonzero skyrmion number. It is one of the aims of the present work to emphasize that similarities in dynamics can be traced to similarities in topological structures. Our study of the details of bubble dynamics in magnetic nanoelements is motivated by interest in fundamental processes in the magnet as well as by the potential of magnetic elements for technological applications.

We discuss the bubble skyrmion number and its relation to dynamics, then we present our results on the dynamics of a bubble with skyrmion number unity and show that it exhibits gyrotropic motion, then we show that a bubble with skyrmion number unity can be switched to a different bubble with skyrmion number zero, then we show that a bubble with skyrmion number zero can be switched back to one with skyrmion number unity.

### Bubble Dynamics and Topology

The dynamics of the magnetization vector M is given by the Landau-Lifshitz (LL) equation with a Gilbert damping term. We suppose a material with saturation magnetization Mₛ, exchange constant A and a uniaxial perpendicular anisotropy with constant K. In a rationalized form the LL equation can be written as

$$\frac{\partial m}{\partial τ} = - {α}_{1} m \times f - {α}_{2} m \times ( m \times f ) , \\ f ≡ Δ m - {Qm}_{z} {\hat{e}}_{z} + h + {h}_{ext} , \qquad ( 1 )$$

where m≡M/M, is the normalized magnetization, h≡H/M, and hₑₓₜ≡Hₑₓₜ/Mₛ are the normalized magnetostatic and external fields, Q≡2K/(μ₀Mₛ²) is the quality factor, and ê_{z} is the unit vector in the third (z) magnetization direction (taken to be the easy axis). If α is the dissipation constant then α₁≡1/(1+α²),α₂≡α/(1+α²). The length and time units in Eq. (1) are

lₑₓ≡\sqrt{2A/(μ₀Mₛ²), τ₀≡1/(γMₛ)}, (2)

where γ is the gyromagnetic ratio, and we will present our results in these units.

In the next sections we perform numerical simulations based on the LL equation using the OOMMF micromagnetics simulator. [12] We typically use the parameter values Mₛ=10⁶ A/m, A=10⁻¹¹ J/m, K=1.3×10⁶ J/m, which give

lₑₓ=4 nm, τ₀=4.5 ps, Q=2.1. (3)

These correspond to FePt, although the anisotropy value lies in the lower limit for this material. Our results (when quoted in units of lₑₓ,τ₀) are independent of the specific numerical values.

A magnetic bubble is a circular domain of opposite magnetization in an otherwise uniformly magnetized film perpendicular to the film surface. In a magnetic element of sub-micrometer dimensions such a circular domain can be spontaneously created in the center of the particle and it is a remanent state. The magnetic bubble has a nontrivial topological structure which is only revealed when we consider the in-plane magnetization components, or, in other words, the domain wall between the bubble domain (which we shall consider to point “down”, i.e., m=(0,0,−1)) and the periphery of the particle (which we shall consider to point “up”, i.e., m=(0,0,1)).

The complexity of the magnetization configuration can be quantified by a topological invariant called the skyrmion number. This is defined as

$$N = \frac{1}{4 π} \int n d x d y , n ≡ \frac{1}{2} {ɛ}_{μ v} ( {\partial }_{v} m \times {\partial }_{μ} m ) \cdot m , \qquad ( 4 )$$

where ε_{μv} is the antisymmetric tensor (μ,v=1,2) and n is a topological density which is integrated over the plane. The integration gives an integer value for N in the case of an infinite two-dimensional medium where the magnetization m goes to a constant value at spatial infinity. We expect a deviation from this rule for the present case of a magnetic element. For the purposes of the present paper we shall consider that the plane of integration is the top surface of a disc element. The result for N depends in general on the choice of the plane of integration. However, we expect that the magnetization vector takes the value m≈(0,0,1) on the side surface of the particle. This would guarantee that the integral given in Eq. (4) will be almost independent of the plane of integration and the value of N will be close to an integer. Indeed, N is very close to an integer for materials with very strong anisotropy, as is the case in the present work. In the case of weaker anisotropy significant deviations from an integer value may occur depending on the specific parameters of the system. A non-integer value of N may not change significantly the picture for bubble dynamics, but it would make the theoretical analysis more complicated.

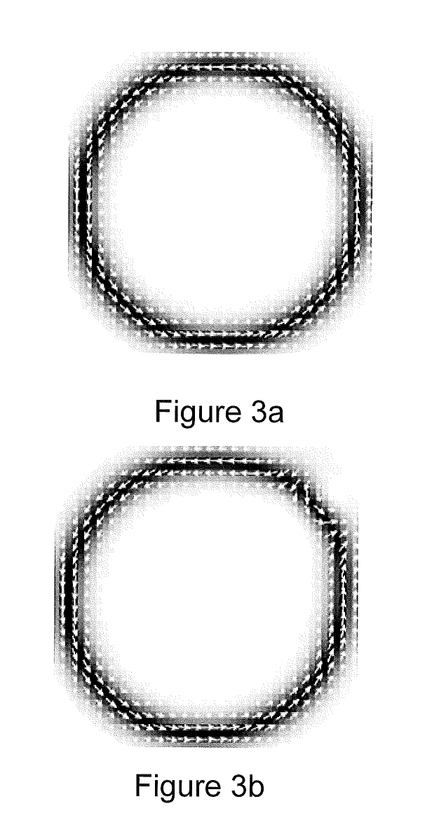

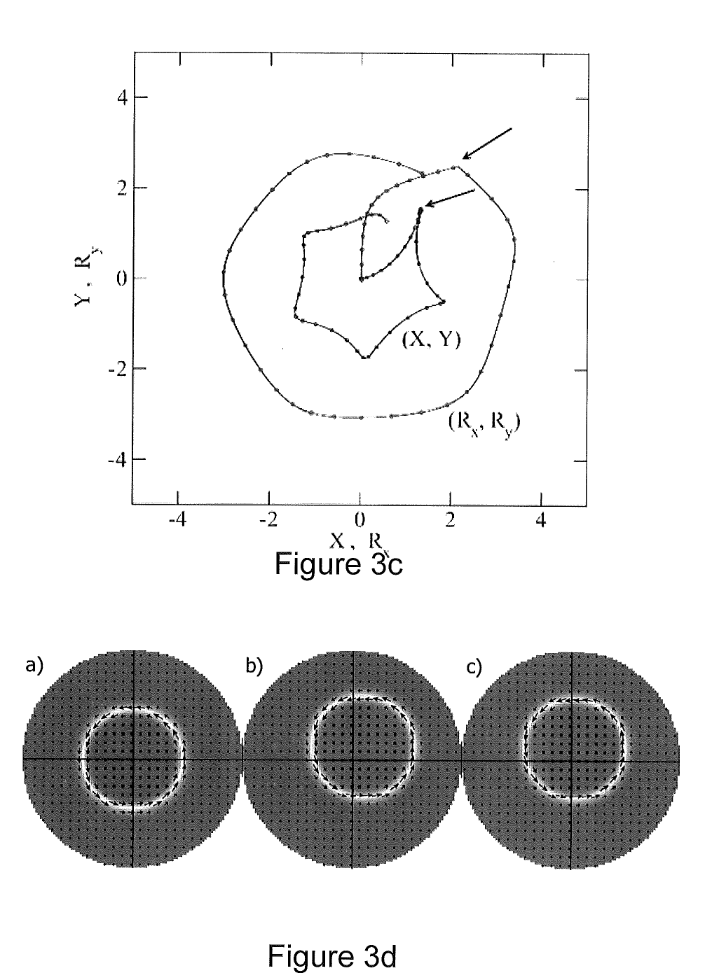

The magnetic bubbles observed previously are most likely axially symmetric, according to symmetry and energy arguments, and they therefore have N=1. Such a bubble is shown in FIG. 3a. A different bubble with N=0 is shown in FIG. 3b, and the differences in the domain walls of the two bubbles are clear. It is useful to note here that the skyrmion number of a vortex takes half-integer values. This is N=±½ for almost all vortices commonly observed in magnetically soft dots, where the sign depends on the vortex “polarity” (that is, the direction of the magnetization in the vortex center).

The skyrmion number N is directly related to the magnetization dynamics as has been seen in many experiments. This effect has been studied where a collective coordinate model for bubble dynamics is expressed with the use of the “gyrocoupling vector”, whose length is a quantity proportional to N. The dynamical properties of topological solitons in two-dimensional ferromagnets with uniaxial anisotropy was later considered. Furthermore, the skyrmion number has direct implications for the unambiguous definition of conservation laws (e.g., the linear momentum) for the Landau-Lifshitz equation. The profound effect of the skyrmion number on vortex dynamics can be seen in recent experiments. For example, the effect of vortex polarity has been studied

In the literature extensive use has been made of a topological number called the winding number S. This gives the number of times that the magnetization vector winds around a full circle as we trace a circle around the center of a vortex or a bubble. For simple structures (like vortices, or the bubbles studied in this paper) S is related to N in a simple way, i.e., N=−½ Sp, that is N depends both on S as well as on the vortex or bubble polarity p. For more complicated topological solutions there is no simple relation between the two topological numbers.

### Gyrotropic Dynamics of the N=1 Bubble

We perform numerical simulations based on the LL equation using the OOMMF micromagnetics simulator. We simulate a magnetic bubble in a disc-shaped magnetic element with diameter D=40lₑₓ (160 nm) and thickness t=8lₑₓ (32 nm). We discretize space on the (x, y) plane using a lattice spacing εx=εy=0.4lₑₓ(1.6 nm) and assume uniform magnetization along the axis of the disc, which is taken to be in the third (z) direction. We start the micromagnetics simulator using as an initial configuration a crude model for a N=1 bubble. In terms of the components of the magnetization in cylindrical coordinates this is

$$( {m}_{ρ} , {m}_{φ} , {m}_{z} ) = \{ \begin{matrix}( 0 , 0 , - 1 ) , & ρ \leq {R}_{a} , \\ ( 0 , 1 , 0 ) , & {R}_{a} < ρ < {R}_{b} , \\ ( 0 , 0 , 1 ) , & ρ \geq {R}_{b} ,\end{matrix} \qquad ( 5 )$$

where ρ is the radial coordinate, Rₐ and R_{b} are constants and they have typically been chosen as Rₐ=0.4D and R_{b}=0.55D. It points “down” in the dot center, “up” in the dot periphery, and azimuthally in the domain wall between the two domains, which is located at Rₐ<ρ<R_{b}. In our first numerical simulation, we evolve Eq. (1) in time using a large dissipation constant and we eventually obtain a static magnetic bubble as a remanent state. This is a circular domain at the center of the dot, which is surrounded by a domain wall. The magnetic configuration is axially symmetric, i.e., the magnetization components mₚ, m_{φ}, m_{z} depend on the cylindrical coordinates p and z only. Such a configuration has a skyrmion number N=1 and it is shown in FIG. 3a.

We aim to study the dynamical behavior of the magnetic bubble described in the preceding paragraph. For this purpose we apply an external magnetic field pointing along the perpendicular direction z. The simplest choice would be a uniform external field, but this would merely make the bubble shrink or expand. [9] Here, we rather aim to study the bubble motion when this is shifted from its equilibrium position at the dot center. This can be achieved by an external magnetic field gradient, as has been shown in the work for magnetic bubbles in continuous films. We choose a field with a gradient along the x direction, i.e,

hₑₓₜ=(0,0,hₑₓₜ), hₑₓₜ=gx, (6)

where g is the dimensionless strength of the gradient. Such a field generates a corresponding gradient of the external field energy. One would expect a translation of the bubble along the field gradient, i.e., along the x direction. The detailed numerical simulation does, however, show quite different dynamics than this expectation as will be explained in the following.

We should to follow the bubble position in order to measure the effect of the external field gradient. There is no obvious absolute measure of this position, but various measures can be defined. A relatively simple one is given by the following moments of the magnetization:

$$X = \frac{\int x ( {m}_{z} - 1 ) d V}{\int ( {m}_{z} - 1 ) d V} , Y = \frac{\int y ( {m}_{z} - 1 ) d V}{\int ( {m}_{z} - 1 ) d V} , \qquad ( 7 )$$

which give the mean position of the bubble domain (where m_{z}=−1, M_{z}=−Mₛ). Another measure of the bubble position is defined as [14]

$${R}_{x} = \frac{\int xn d V}{\int n d V} , {R}_{y} = \frac{\int yn d V}{\int n d V} , \qquad ( 8 )$$

where n is the topological density defined in Eq. (4). Eqs. (8) give the location of the nontrivial topological structure of the bubble. This is the guiding center of the bubble. The latter definition is obviously only valid when N≠0. The moments of the topological density (8) are significant for the dynamics as they are proportional to the components of the linear momentum of the magnetization field within the LL equation. Their short-time behavior gives a qualitatively correct description of the unusual skew deflection of magnetic bubbles under a field gradient.

In the series of numerical simulations which we present in the following we use as an initial condition the static magnetic bubble in the dot center which we have previously found. We apply the external magnetic field (6), choose a realistic dissipation constant α=0.01, and follow the dynamics of the bubble in time, as given by the LL equation (1). The strength of the field gradient, in this simulation, is chosen to be g=−0.0025. This value practically means that the external field is hₑₓₜ=0.05M, at the left end of the dot (at x=−D/2=−20lₑₓ, and it is gradually reduced to become hₑₓₜ=at the right end of the dot (at x=D/2=20lₑₓ) The field is applied for a time period of τ=44.5τ₀ (200 ps) and it is then switched-off completely.

The bubble orbit as given by the moments of the magnetization (7), and also by the moments of the topological density (8) is shown in FIG. 3c. During the application of the external field, the moments (7) give a skew deflection of the bubble with respect to the field gradient towards the first quadrant. The moments (8), indicate more clearly a motion along the direction perpendicular to the field gradient during the initial stages of the simulation. It is impressive that R_{y} appears to follow a rectilinear motion for times τ<11τ₀ (50 ps) with a measured velocity

$$( \frac{d {R}_{x}}{d τ} , \frac{d {R}_{y}}{d τ} ) \approx ( 0.0 , 0.095 ) \frac{{l}_{ex}}{{τ}_{0}} . \qquad ( 9 )$$

This dynamical behavior is in accordance with N. Papanicolaou and T. N. Tomaras, Nucl. Phys. B, 425 (1991); and S. Komineas and N. Papanicolaou, Physica D, 81 (1996) (though these refer to infinite continuous films). The approach of these references has produced formulae for the initial velocity (at τ=0) of the bubble. We reproduce these formulae in the present notation for convenience.

$$\frac{d {R}_{x}}{d τ} = - {α}_{2} \frac{gv}{4 π Nt} , \frac{d {R}_{y}}{d τ} = {α}_{1} \frac{g μ}{4 π Nt} , \qquad ( 10 )$$

where t is the film thickness, p is the total magnetization in the third direction, and v is essentially the anisotropy energy:

$$μ = \int ( {m}_{z} - 1 ) d V , v = \frac{1}{2} \int ( 1 - {m}_{z}^{2} ) d V . \qquad ( 11 )$$

All quantities are measured in units (2). In order to find numerical values, we substitute in (11) the configuration of the static bubble and find μ/t=−815, v/t=41. We then obtain

$$( \frac{d {R}_{x }}{d τ} , \frac{d {R}_{y}}{d τ} ) = ( 0.00008 , 0.16 ) \frac{{l}_{ex}}{{τ}_{0}} , \qquad ( 12 )$$

which clearly gives a deflection of the bubble perpendicular to the direction of the field gradient. The velocity dRy/dr is much larger than dR_{y}/dτ because α₁ [symbol] α₂ (for α=0.01), and because the bubble total magnetization μ (which is proportional to the bubble area) is much larger than its anisotropy energy v (which is proportional to the length of the bubble domain wall).

Result (12) gives correctly the tendency of (Rₓ, R_{y}) to move along the y direction, although the calculated velocity value is about 60% in error. However, one should keep in mind that Eqs. (10) were derived for infinite films and they hold only at the very beginning of the process.

When the external field is switched-off at τ=44.5τ₀ (200 ps) the bubble is in the first quadrant at (Rₓ,R_{y})=(2.1,2.5)lₑₓ, while (X,Y)=(1.3,1.6)lₑₓ. We then observe an almost circular motion of the (Rₓ,R_{y}) orbit of the particle with a radius ˜3lₑₓ. The type of motion for (X,Y) is more involved and its trajectory is roughly a pentagon, as seen in FIG. 3c. The period of this almost periodic motion is approximately T=230τ₀ (lnsec) (i.e., frequency f=1 GHz).

The bubble, certainly, does not move as a rigid body around the dot center. The details of its motion can be seen in the three snapshots presented in FIG. 3d. The initial state is shown in FIG. 3da. (This is the same configuration as in FIG. 3a except that the whole element is shown now.) FIG. 3db shows the configuration at time τ=44.5τ₀, that is at the end of the application of the external field. While the bubble preserves its general structure it has apparently shifted to the first quadrant. FIG. 3dc shows the bubble at time τ=267τ₀ (1200 ps) when it has almost completed a full circle. The deformation of the bubble is small and also the details of the domain wall structure are preserved. However, such a coherent motion does not happen for large field gradients as will be explained in the next section.

We have also repeated the simulation with a stronger field gradient g=−0.005. The results are similar to those described in the preceding paragraphs. The initial velocity for the bubble is now dR_{y}/dτ=0.19, i.e., twice the value given in (9). Thus the bubble velocity seems to be proportional to g in agreement with the prediction of Eq. (10). The bubble is later set in a circular motion around the center of the dot. The period of this motion is similar to that given in the g=−0.0025 case (i.e., T∞1 nsec), although we obtain a displacement of the bubble from the dot center significantly larger, roughly twice that shown in FIG. 3c.

### Switching of the N=1 Bubble

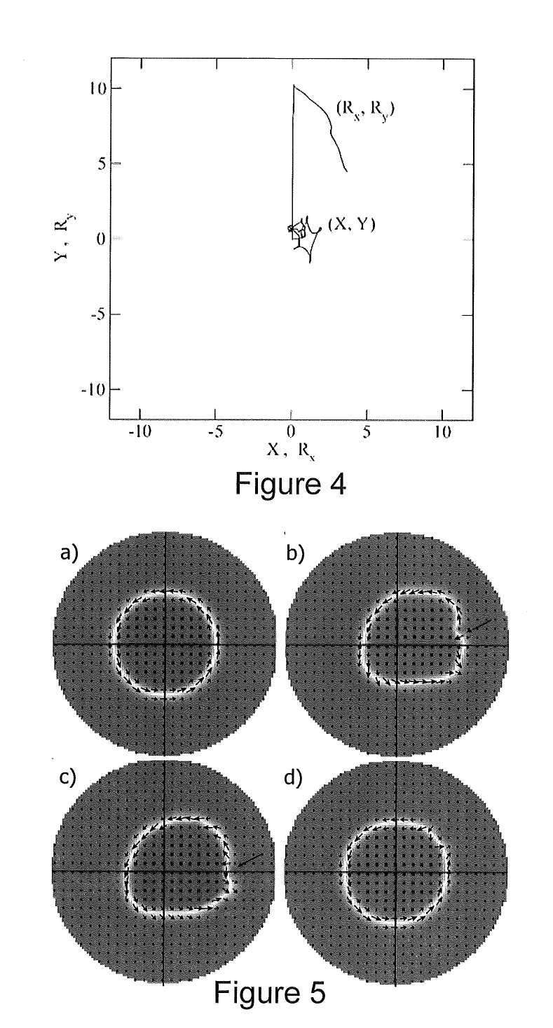

We further study the response of the magnetic bubble to field gradients larger than those used in the previous section. We typically use in this section a large field gradient strength g=−0.025. The field is applied only until τ=10τ₀ (45 ps). At initial times the coordinate R_{y} is rapidly increasing while Rₓ remains almost zero for τ<10τ₀. This motion is shown in FIG. 4. We observe a linear increase of R_{y} until the field is switched off. The measured velocity dR_{y}/dτ=1.0 is approximately 10 times larger than the velocity found for g=−0.0025 in the previous section. This shows that dR_{y}/dτ is proportional to g. The velocity predicted by Eq. (10) is dR_{y}/dτ=1.6, and it is roughly in agreement with the numerical results (as discussed in the g=−0.0025 case). The position vector (X,Y) is displaced from the origin by a small distance −lₑₓ, as seen in FIG. 4. This is a much shorter distance than that observed in the previous section (see FIG. 3c). This is because the field gradient is now applied for a much shorter time. Unlike the velocity for (Rₓ,R_{y}), the velocity for the coordinates (X,Y) is apparently not proportional to the strength of the field gradient g.

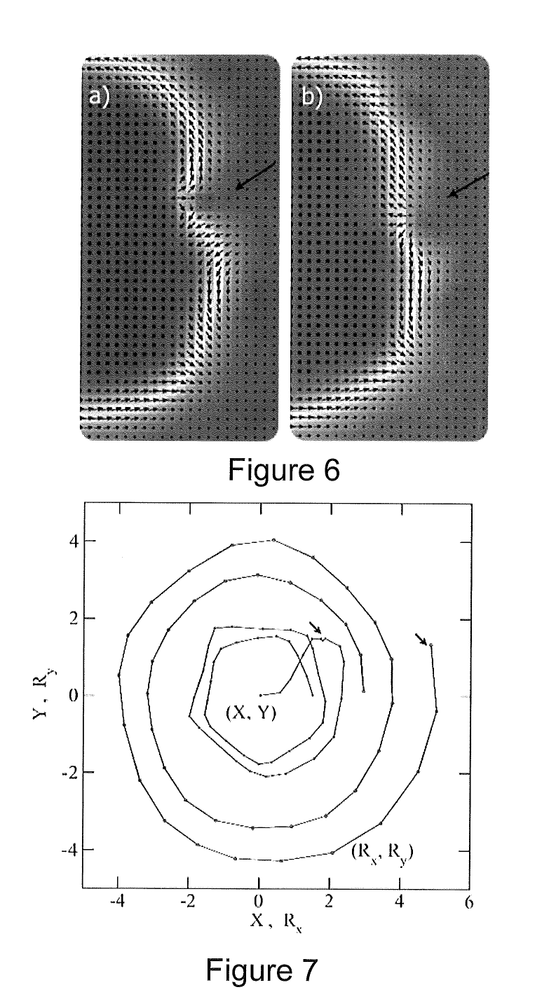

After the external field gradient is switched off the position of the bubble, measured by (Rₓ,R_{y}), takes a sharp turn and appears to start a cyclic motion around the dot center similar to what was described in above. On the other hand, the coordinates (X,Y) follow a non-regular path close to the dot centre. FIG. 5 shows snapshots of the simulation. At some later time significant gradients of the magnetization vector develop at the bubble domain wall. For example, at τ=83τ₀ (375 ps) (FIG. 5b) a part of the wall includes so-called vertical Bloch lines (VBLs). At τ=85.5τ₀ (385 ps) an abrupt change of the magnetization occurs at the region of the domain wall where the VBLs had developed. This is accompanied by a burst of spin waves. FIG. 5c shows the bubble after the domain wall has changed. FIG. 6 shows magnifications of a part of the bubble corresponding to FIGS. 5b,c. A pair of VBLs is now part of the domain wall.

Configurations with VBLs have been studied within the context of bubbles in films as reviewed in Ref. malozemoff. A pair of VBLs can be winding, when the magnetization winds 22r as we move across them in the domain wall, or non-winding when the magnetization has a local net winding of zero (including a π and −π winding as we move across the wall). The pair in FIG. 6b is a winding pair.

The transformation of the initial VBLs to a single pair of VBLs is a discontinuous process. Such discontinuous processes are normally impossible to induce because an infinite energy barrier would have to be overcome. In magnetic systems the energy barrier would be due to the exchange energy at regions with large magnetization gradients. However, the exchange energy of a two-dimensional magnetization configuration (e.g., a pair of VBLs) as this is shrinking is a finite constant. This is due to the scale invariance of the exchange energy in two dimensions. Since the bubble is a quasi-two dimensional magnetic configuration the exchange energy in the region of the approaching VBLs will not give an infinite energy barrier.

We should note here that a discontinuous change of the magnetization cannot, in principle, be described by micromagnetics on a discrete numerical mesh. However, since in the present case no singularities in the energy are involved, one could argue, at least heuristically, that the numerical solution on the discrete lattice does simulate correctly the process which actually occurs in the atomic lattice of the material. Such discountinuous changes have been reported in experiments in films.

Although the magnetic bubble seems to remain intact in the dot even after the modification of the domain wall, a dramatic change has indeed occurred at the microscopic level. To show this we calculate the skyrmion number (4) of the magnetization. This is very close to unity for the initial bubble and it remains almost constant until the discontinuous change of the magnetic configuration occurs. At time τ=85.5τ₀ the skyrmion number N changes almost instantly to a value close to zero. Thus the discontinuous nature of the process of the annihilation of VBLs is reflected in an abrupt change from N=1 to N=0. The magnetic bubble with N=0 is essentially different than the initial bubble with N=1.

The coordinates (Rₓ,R_{y}) do not give a well-defined measure of the bubble position for N=0 since the denominators in Eq. (8) vanish. The bubble position can be followed by the coordinates (X,Y) which are shown in FIG. 4. These take small values and they follow an orbit which is complicated and not a periodic one. That is, there is no trace of a gyrotropic (circular) motion of the bubble around the dot center, in contrast to the case of the N=1 bubble. We relegate further discussion of this point until the end of the next section.

For longer times the system will relax to a remanent state due to dissipation. Since, the relaxation process with our standard dissipation constant α=0.01 takes prohibitively long simulation time, we actually use (for times well after τ=85.5τ₀) a large α=1 only for the purpose of quickly finding the remanent state. The process of FIG. 5 eventually relaxes to an almost cylindrical bubble with N=0 in the dot center shown in FIG. 5d. The domain wall of the latter bubble is shown more clearly in FIG. 3b, where a pair of winding VBLs is seen. The two VBLs apparently attract each other due to their magnetostatic field. We further discuss the details of the N=0 bubble in the next section.

In conclusion, the application of a strong magnetic field gradient on a dot which is in a bubble state with N=1 has eventually switched it to a bubble with N=0. We add that the field gradient value g=−0.025 used in this section is indicative. We have also tried a field gradient g=−0.0125 and have obtained the switching process. Furthermore, we have achieved switching events while keeping the same field gradient (g=−0.025) but for different field pulse durations.

Switching of the N=1 magnetic bubble into a N=0 bubble has apparently been observed for the first time in Ref. hsu74. A garnet film was used which was exchange coupled to a magnetic layer. Apart from the bias field (which is necessary in order to sustain a bubble in a film) an in-plane field was applied. On top of these fields, 100 nsec long pulses of a field gradient perpendicular to the film were applied which led to bubble switching. In other experiments with bubbles in continuous films changes of bubble dynamics have been observed which have been attributed to changes of the bubble skyrmion number.

### Switching of the N=0 Bubble

The N=0 bubble was shown to be a remanent magnetic state. The N=1 bubble has energy E=2.797×10⁻¹⁶ J while the N=0 bubble has E=2.824×10⁻¹⁶ J. Thus the latter is an excited metastable state. Its domain wall contains a pair of winding VBLs which are located close together. Magnetic charges are accumulated around the VBLs, thus creating a strong magnetostatic field in their vicinity.

We study in this section the dynamics of a N=0 bubble in a nanodisc, following a procedure analogous to that above. We perform numerical simulations using the remanent bubble state, in the dot center, with skyrmion number N=0 (i.e., the state shown in FIG. 5d and in FIG. 3b). We apply a strong field gradient (6) with g=−0.025. The field is switched off at time τ=55τ₀ (250 ps). We observe that the bubble is displaced from the center of the dot. The orbit of the bubble as given by the moments of Eqs. (7) is shown by the dashed line in FIG. 7. It moves in the first quadrant under the influence of the field.

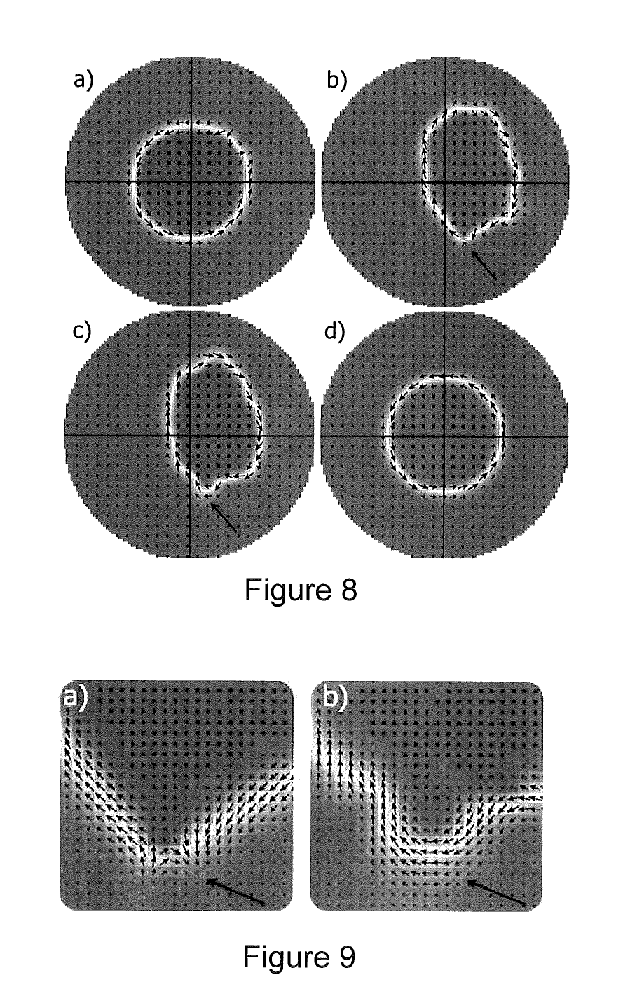

The structure of the bubble domain wall is getting increasingly complicated under the influence of the field gradient as the pair of winding VBLs are drifting around the wall. The complicated dynamics of the domain wall continues even after the field is switched off. FIG. 8 shows snapshots of the simulation. At time τ=95.5τ₀(430 ps) we observe that the two VBLs come close together (FIG. 8b) and thus large magnetization gradients develop in a very short region of the domain wall (indicated by an arrow). FIG. 9a shows a magnification of the part of the domain wall which contains the pair of VBLs. This leads to annihilation of the pair of VBLs as shown in FIG. 8c at time τ=98τ₀(440 ps). FIG. 9a shows that the VBLs have become adjacent just before the annihilation while FIG. 9b shows a magnification of the part of the domain wall where the VBL pair annihilation took place.

The annihilation of a pair of winding VBLs is a discontinuous process. As also mentioned in the previous section, such a process should be possible in the present two-dimensional bubble configurations.

The discontinuous nature of the process of annihilation of the pair of winding VBLs is reflected in an abrupt change of the skyrmion number from N=0 to N=1 which happens precisely at the time of the annihilation of VBLs.

The N=1 bubble is located off-center, at the moment of its creation. The trajectory of the bubble as given by Eq. (7) and by Eq. (8) is shown in FIG. 7. We observe that once the skyrmion number becomes unity the bubble starts a circular motion around the dot center. The bubble motion is damped due to dissipation, it follows a spiraling orbit and it eventually remains static at the dot center. It is remarkable that the bubble motion is reflected in a rather smooth circular trajectory for the moments of the local vorticity (solid line) compared to an angled (nearly pentagonal) curve for the moments of m_{z} (dashed line). The frequency of rotation is approximately 1 GHz. The above findings concerning the circular motion of the N=1 bubble are fully consistent with the results described above.

The results of the present and the previous sections indicate differences between the dynamics of the N=0 and the N=1 bubble. We have shown that the N=1 bubble, when this is not in the dot center, goes on a gyrotropic motion as seen in FIG. 3c and in FIG. 7. The behavior of a N=0 bubble is however less clear. We have described above that the N=0 bubble created during a dynamical process does not undergo a circular motion around the dot center. We did not clearly observe a gyrotropic motion for the N=0 bubble in this section either. Further numerical simulations support these findings.

We have thus presented a numerical study for the unusual dynamical behavior of a bubble in a magnetic nanoelement under an external magnetic field gradient. It has been shown that a bubble with skyrmion number N=1 is deflected at an angle to the field gradient. The details of this skew deflection of the bubble confirm previous theoretical studies. When the external field is switched off the bubble is set on a gyrotropic motion around the center of the nanoelement. Previous experimental and theoretical studies on this subject refer to the dynamical behavior of magnetic bubbles in infinite films. The present study has applied the idea of an external magnetic field gradient in the context of a magnetic bubble in a nanoelement.

A strong enough field gradient was shown to affect the bubble structure profoundly and it induced a switching of the N=1 bubble to a bubble with skyrmion number N=0. The latter is shown to be a remanent state of the magnetic system. Application of a similar field gradient to the N=0 bubble induces a switching back to the original N=1 bubble. The ultra-fast switching between the two bubbles is achieved for times below one nanosecond which could prove to be a significant advantage for applications. Although the two bubbles look very similar regarding their perpendicular component of the magnetisation they are essentially different magnetic states. We did not observe a simple gyrotropic motion of the N=0 around the center of the nanoelement. However, the detailed features and especially the dynamics of this bubble need further investigation.

A dramatic difference between the dynamics of bubbles with N=0 and N 0 is anticipated. Furthermore, the skyrmion number has direct implications for the unambiguous definition of conservation laws (e.g., the linear momentum) for the Landau-Lifshitz equation. Eqs. (10) have been derived based on the latter theory. Their denominators vanish for N=0 thus implying that this should be treated as a separate special case.

This work (and aspects and embodiments of the invention) extend to other topological magnetic states such as magnetic bubbles. While almost all vortices observed so far have the same magnetization configuration, bubbles may have a variety of topological structures. This enriches the subject significantly and opens new possibilities not only for theoretical and experimental work but possibly also for technological applications. A systematic study for the excitation spectrum of bidomain and multidomain bubbles shows several interesting resonances indicating a variety of dynamical behaviors.

### REFERENCES

[1] C. Moutafis et al, Phys. Rev. B 76, 104426 (2007)
[2] A. P. Malozemoff and J. C. Slonczewski, Magnetic domain walls in Bubble Materials, New York, Academic Press (1979)
[3] T. H. O'Dell, Ferromagnetodynamics: The Dynamics of Magnetic Bubbles, Domains, and Domain Walls, London, MacMillan (1981)
[4] Hubert, Magnetic Domains, Berlin, Springer (1998)
[5] Ta-lin Hsu, AlP Conference Proceedings, 24, 624 (1974)
[6] Ta-lin Hsu, Patent No, Method and Apparatus for the Controlled Generation of Wall-Encoded Magnetic Bubble Domains
[7] P. Dekker and J. C. Slonczewski, Appl. Phys. Lett. 29, 753 (1976)
[8] A. A. Thiele, Phys. Rev. Lett. 30, 230 (1973)
[9] S. Komineas et al, Phys. Rev. B 71, 060405 (R) (2005)
[U1] http://techon.nikkeibp.co.jp/article/HONSHI/20080226/148038/ and http://techon.nikkeibp.co.jp/article/HONSHI/20080226/148038/fig12.jpg

### FURTHER REFERENCES

A. A. Thiele, J. Appl. Phys., 377 (1974).
M. Hehn, K. Ounadjela, J. P. Bucher, F. Rousseaux, D. Decanini, B. Bartenlian, and C. Chappert, Science, 1782 (1996).
G. D. Skidmore, A. Kunz, C. E. Campbell, and E. D. Dahlberg, Phys. Rev. B, 012410 (2004).
J. K. Ha, R. Hertel, and J. Kirschner, Europhys. Lett., 810 (2003).
C. Moutafis, S. Komineas, C. A. F. Vaz, J. A. C. Bland, P. Eames, Phys. Rev. B, 214406 (2006).
S. B. Choe, Y. Acremann, A. Scholl, A. Bauer, A. Doran, J. Stöhr, and H. A. Pademore, Science, 420 (2004).
M. J. Donahue and D. G. Porter, OOMMF User's Guide, Interagency Report NISTIR 6376, National Institute of Standards and Technology, Gaithersburg, Md. (1999), http://math.nist.gov/oommf/.
B. A. Ivanov and V. A. Stephanovich, Phys. Lett. A, 89 (1989).
N. Papanicolaou and T. N. Tomaras, Nucl. Phys. B, 425 (1991).
S. Komineas and N. Papanicolaou, Physica D, 81 (1996).
K. S. Buchanan, P. E. Roy, M. Grimsditch, F. Y. Fradin, K. Yu. Guslienko, S. D. Bader, and V. Novosad, Nature Physics, 172 (2005).
O. A. Tretiakov and O. Tchernyshyov, Phys. Rev. B, 012408 (2007).
R. Rajaraman, Solitons and Instantons (North Holland, Amsterdam, 1982).
N. Vukadinovic and F. Boust, Phys. Rev. B, 014420 (2007).
N. Vukadinovic and F. Boust, Phys. Rev. B, 184411 (2008).

No doubt many other effective alternatives will occur to the skilled person. It will be understood that the invention is not limited to the described embodiments and encompasses modifications apparent to those skilled in the art lying within the spirit and scope of the claims appended hereto.

1. A method of storing one or more bits of information, the method comprising: forming a magnetic bubble; and storing a said bit of information encoded in a topology of a domain wall of said magnetic bubble.

2. A method as claimed in claim 1 wherein said storing comprises storing said bit encoded using S=0 and S=1 status of said domain wall, in particular wherein said S=1 states of said domain wall, wherein said S=1 state comprises a symmetric state of said domain wall and said S=0 states includes at least one winding rotation of a magnetisation vector of said domain wall in moving along a border of said bubble defined by said domain wall.

3. A method as claimed in claim 1 further comprising confining said magnetic bubble in an island of magnetic material.

4. A method as claimed in claim 3 wherein said confining is such that said bubble is substantially stable without application of a bias field.

5. A method as claimed in claim 1, further comprising changing a value of a said bit of information by applying to said magnetic bubble a magnetic field gradient pulse or electrical current excitation.

6. A magnetic storage device for storing one or more bits of information, the device comprising:
a plurality of islands of magnetic material;
a plurality of magnetic bubbles, at least one per said island;
wherein said bits of information are stored encoded in a topology of a domain wall of said magnetic bubble.

7. A magnetic storage device as claimed in claim 6 wherein said bits of information are stored encoded in said topology of said domain wall of said magnetic bubble using at least one of a three-ring state and a single domain.

8. A magnetic storage device as claimed in claim 6 further comprising a mechanism to apply a magnetic field gradient pulse or an electrical current excitation to said magnetic bubble to change a value of a said stored bit.

9. A method as claimed in claim 1, wherein a said magnetic bubble has a maximum dimension of less than 1 μM.

10. A method of reading a bit of information, in particular stored using the method as claimed in claim 1, the method comprising applying a magnetic field or an electrical current excitation to induce different dynamic responses from said topology of said domain wall, and detecting a said dynamic response to identify a said topology of said domain wall of a said magnetic bubble and hence deduce a value of a stored said bit of information.

11. A method of reading a bit of information as claimed in claim 10 wherein said detecting a said dynamic response is by means of magnetoresistive measurement.

12. A method of reading a bit of information as claimed in claim 10 wherein said applying of said magnetic field comprises applying a magnetic field to cause rotation of a topological defect in said domain wall, and wherein, said detecting of said dynamic response comprises detecting said rotation.

13. A method of reading a bit of information as claimed in claim 10 wherein said applying of said magnetic field comprises applying a field to change a size of a said magnetic bubble.

14. A method of reading a bit of information as claimed in claim 10, wherein said applying of said magnetic field comprises tuning said magnetic field or said electrical current excitation to an eigenfrequency of said S=1 state of said domain wall.

15. A method of reading a bit of information as claimed in claim 10 wherein said applying of said magnetic field comprises applying a field gradient pulse or electrical current excitation such as charge current or spin polarized current.

16. A device for reading a bit of information in particular stored using the method as claimed in claim 1, the device comprising:
means for applying a magnetic field or electrical current excitation such as charge current or spin polarized current to induce different dynamic responses from said topology of said domain wall; and means for detecting a said dynamic response to identify a said topology of said domain wall of a said magnetic bubble and hence deduce a value of a stored said bit of information.

17. A device as claimed in claim 6, further comprising a pair of conductors one to either side of a said magnetic bubble or a said island for writing or reading a topological state of a said domain wall of said magnetic bubble.

18. A method as claimed in claim 3, wherein a said island of magnetic material has a maximum dimension of less than 1 μm.

19. A magnetic storage device as claimed in claim 6, wherein said island of magnetic material has a maximum dimension of less than 1 m.

20. A method as claimed in claim 5, wherein said electrical current excitation comprises an electrical charge current or a spin polarized current.

21. A magnetic device as claimed in claim 8, wherein said electrical current excitation comprises an electrical charge current or a spin polarized current.

22. A method as claimed in claim 10, wherein said electrical current excitation comprises an electrical charge current or a spin polarized current.
